(19) United States
(12) Patent Application Publication
(10) Pub. No.: US 2020/0328017 A1
(43) Pub. Date: Oct. 15, 2020

(54) MAGNETIC MOUNT CONNECTOR FOR A PORTABLE ELECTRONIC DEVICE

(71) Applicant: Encased Products Inc., East Rutherford, NJ (US)

(72) Inventor: Akiva Benyamin ISENBERG, Spring Valley, NY (US)

(73) Assignee: Encased Products Inc., East Rutherford, NJ (US)

(21) Appl. No.: 16/380,696

(22) Filed: Apr. 10, 2019

(51) Int. Cl. H01F 7/02; H05K 5/02; F16M 11/04; H04M 1/11; B60R 11/02

(52) U.S. Cl. CPC H01F 7/0252; H05K 5/0204; B60R 2011/0071; H04M 1/11; B60R 11/0241; F16M 11/04

(57) ABSTRACT

A mount connector for a portable electronic device having a protrusion extending from a surface of the portable electronic device or a surface of a cover of the portable electronic device includes: a body comprising a first part, the first part of the body comprising: a first cavity having a first opening on an external surface of the first part of the body, wherein the first cavity and first opening are sized and shaped to accept and limit movement of the protrusion in at least one direction while the mount connector is connected to the electronic device, and a magnetic surface located on a portion of the external surface of the first part of the body surrounding the first opening, wherein the magnetic surface is configured to connect the mount connector to the portable electronic device, the cover of the portable electronic device, or a metal surface integrated therewith.

### FIELD OF THE INVENTION

The present invention relates to mounting devices for portable electronic devices, and, more particularly, to a magnetic mounting connector for connecting a mounting device to a back of a portable electronic device having a protrusion, such as a clip or grip, extending from the back of the electronic device or from the back of a cover of the electronic device.

### BACKGROUND OF THE INVENTION

Portable electronic devices, such as cell phones and tablets, and the cases made to protect them, often have a protrusion which is affixed to or otherwise integrated with the back of the electronic device or cover of the electronic device, such as a grip, ring holder, or clip, e.g., to make it easier to hold the electronic device, to act as a stand to position the electronic device for viewing, to attach to a belt, to wrap a wire, such as a head phone wire, around, to hold cards, to help mount the device, etc.

Often times it is either infeasible or unwanted to remove such a protrusion or the cover of the electronic device if the protrusion is integral to the cover of the electronic device. For example, some grips/holders/clips are not removably connectable because they are attached to a surface of the electronic device or cover of the electronic device by adhesive, or are manufactured therewith. Typically, if the grip/holder/clip is connected to the electronic device by adhesive, once that grip/holder/clip is detached the adhesive loses its strength. Some grips/holders/clips are integral with the cover of the electronic device or affixed thereto, and often it is unwanted to remove a cover of the electronic device out of fear of losing the cover, damaging the electronic device, and/or having to hold onto the cover separately, for example, in order to mount a device in a device mount.

Some solutions to avoid removal of such grips/holders/clips while allowing the electronic device to be mounted, for example in a car, are to attach a magnet to the same surface as the grip/holder/clip, e.g., above or below, facing away from the back of the electronic device or the case so that the electronic device or case can be removably attached to a metallic mounting device affixed to an internal surface of the vehicle via the magnet. Alternatively, a magnet may be mounted to an internal surface of the vehicle and a metallic attachment may be affixed to a surface on the back of the electronic device or case (e.g., above or below any grips/holders/clips) so that the electronic device and/or case can be removably attached to the magnetic mounting device via the metallic attachment. In yet other embodiments, a magnet or metallic device may be affixed to the grip/holder/clip itself and used in similar fashion. A problem with such solutions is that, while the metallic surface functions to resist movement of the grip/holder/clip away from a magnetic surface of the mounting device (or vice versa), the magnetic surface does not effectively resist movement of the grip/holder/clip in at least one direction in a plane parallel to the magnetic surface, e.g., laterally, upward, downward, angularly, etc. For example, if the plane parallel to the magnetic surface extends in the x and y directions, then the magnetic surface would mainly resist a movement away from the mounting device in a z direction perpendicular to both the x and y directions, due to the magnetic attraction.

However, this would only provide negligible frictional resistance in a direction in the x-y plane, e.g., when the metal surface is pressing against a magnetic portion of the mounting device. It would take a prohibitive amount of magnetic force to increase the frictional resistance in a direction in the x-y plane such that the magnetic surface alone could effectively prevent the electronic device from moving in a given direction in the x-y plane. For example, besides increasing costs by using a stronger magnet, one may no longer be able to remove the electronic device by hand from the mount once they are in contact due to the increased magnetic attraction, or the magnetic surface may cause unintended attraction with other metal objects in an inconvenient or potentially dangerous way.

Thus, simply using a magnetic surface can be problematic when the mounting device is, e.g., for automotive use where potential collisions and/or inertial forces can cause the grip/holder/clip to move in the above defined x-y plane, for example, when the automotive vehicle is struck from a side or when the automotive vehicle is turning.

### SUMMARY OF THE INVENTION

Embodiments of the invention provide a mount connector for a portable electronic device having a protrusion extending from a surface of the portable electronic device or a surface of a cover of the portable electronic device, the mount connector including: a body comprising a first part, the first part of the body including: a first cavity having a first opening on an external surface of the first part of the body, wherein the first cavity and first opening are sized and shaped to accept and limit movement of the protrusion in at least one direction while the mount connector is connected to the electronic device, and a magnetic surface located on a portion of the external surface of the first part of the body surrounding the first opening, wherein the magnetic surface is configured to connect the mount connector to the portable electronic device, the cover of the portable electronic device, or a metal surface integrated therewith.

In some embodiments, the mount connector further includes a height of the first opening and a height of each part of a first section of the first cavity is greater than or equal to a height of a greatest cross-sectional area of the protrusion; a width of the first opening and a width of each part of the first section of the first cavity is greater than or equal to a width of the greatest cross-sectional area of the protrusion; and a height and a width of a second section of the first cavity is equal to the height and width of the greatest cross-sectional area of the protrusion, such that the second section of the first cavity limits the protrusion from moving in at least one direction within an X-Y plane parallel to at least one of the first opening and the first cavity when the first cavity holds the protrusion; and wherein: the width of the first opening and the first section of the first cavity runs in an X direction; the height of the first opening and first section of the first cavity runs in a Y direction, wherein the Y direction is perpendicular to the X direction.

In some embodiments, the mount connector further includes a height and width of the first opening and each part of a first section of the first cavity is equal to a height and width of the greatest cross-sectional area of the protrusion, such that the first cavity prevents the protrusion from moving in at least one direction of a plane of an X direction and a Y direction when the first cavity holds the protrusion; wherein: the width of the first opening and first section of the first cavity runs in the X direction; the height of the first opening and first section of the first cavity runs in the Y direction, wherein the Y direction is perpendicular to the X direction.

In some embodiments, the mount connector further includes a plate, the plate including: an adhesive surface configured to be attached to the surface of the portable electronic device or the back of the cover of the portable electronic device; a metal surface, located on an opposite face of the plate, wherein the magnetic surface and the metal surface are sized and shaped to magnetically connect the plate and the body; and a plate aperture extending from the adhesive surface to the metal surface, the plate aperture sized and shaped to pass over the protrusion when the magnetic surface and the metal surface are magnetically connected.

In some embodiments, the plate aperture, the first opening, and each part of the first cavity each have a height that is greater than or equal to a height of a greatest cross-sectional area of the protrusion; and the plate aperture, the first opening, and each part of the first cavity each have a width that is greater than or equal to a width of the greatest cross-sectional area of the protrusion. In some embodiments, the cross-sectional area of at least one of the plate aperture, the opening, and at least a part of the first cavity is equal to a greatest cross-sectional area of the protrusion. In some embodiments, a surface area of the magnetic surface has a same size and shape as a surface area of the metal surface.

In some embodiments, the mount connector further includes a second part of the body, the second part of the body comprising a second cavity having a second opening on an external surface of the second part of the body. In some embodiments, the second cavity comprises a female connector configured to connect with a male connector of a mounting device. In some embodiments, the mounting device is a car mount. In some embodiments, the second opening of the second part of the body is located on a side of the body that is at least 90° from a side of the body than the first opening of the first part of the body is located, such that the second cavity is accessible through the second opening while the mount connector is connected to the electronic device.

In some embodiments, the mount connector further includes a height of the first opening is greater than a height of the second opening; and a width of the first opening is greater than a width of the second opening. In some embodiments, each part of the first part of the body has a greater cross-sectional area than each part of the second part of the body. In some embodiments, the second part of the body extends from a back surface of the first part of the body, and the back surface of the first part of the body is located on an opposite side of the first part of the body than the first opening.

Further embodiments of the invention provide a mount connector for a portable electronic device having a protrusion extending from a back of the portable electronic device or a back of a cover of the portable electronic device, the mount connector including: a body including: a first cavity having a first opening on an external surface of the body, and a magnetic surface located on a portion of the external surface of the body surrounding the first opening; and a plate including: an adhesive surface configured to be attached to the back of the portable electronic device or the back of the cover of the portable electronic device; a metal surface, located on an opposite face of the plate, wherein the magnetic surface and the metal surface are sized and shaped to magnetically connect the plate and the body; and a plate aperture extending from the adhesive surface to the metal surface.

In some embodiments, a surface area of the magnetic surface and the metal surface are sized and shaped for magnetically connecting the magnetic surface and the metal surface. In some embodiments, the plate aperture, the first opening, and each part of a first section of the first cavity each have a height greater than or equal to a pre-determined height; the plate aperture, the first opening, and each part of the first section of the first cavity each have a width greater than or equal to a pre-determined width; and at least a part of the first cavity has a height and width that are equal to the pre-determined height and the pre-determined width, respectively. In some embodiments, the mount connector further includes a second cavity having a second opening on the external surface of the body.

Further embodiments of the invention provide a mount connector for a portable electronic device having a protrusion extending from a back of the portable electronic device or a back of a cover of the portable electronic device, the mount connector including: a body including a first part, the first part of the body including: a first cavity having a first opening on an external surface of the first part of the body, wherein the first cavity and first opening are sized and shaped to accept and limit movement of the protrusion in at least one direction while the mount connector is connected to the electronic device, and a second part of the body, the second part of the body comprising a second cavity having a second opening on an external surface of the second part of the body. In some embodiments, first cavity is configured to limit movement of the protrusion in at least one direction within a plane parallel to at least one of the first opening and the first cavity.

Systems and methods according to embodiments of the above may also be provided. These and other aspects, features, and advantages will be understood with reference to the following description of certain embodiments of the invention.

### BRIEF DESCRIPTION OF THE DRAWINGS

In order for the present invention to be better understood and for its practical applications to be appreciated, the following Figures are provided and referenced hereafter. It should be noted that the Figures are given as examples only and in no way limit the scope of the invention. Like components are denoted by like reference numerals.

FIGS. 1A-B are perspective views of a mount connector for an electronic device, according to some embodiments of the invention.

FIGS. 2A-C are perspective views of a mount connector for an electronic device in an unattached position, according to some embodiments of the invention.

FIG. 3 is a perspective view of a mount connector holding a protrusion that is extendable from a back of an electronic device, and not connected to a plate, according to some embodiments of the invention.

FIG. 4 is a perspective view of a mount connector in an attached position, according to some embodiments of the invention.

It will be appreciated that, for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following description, various aspects of the present invention are described. For purposes of explanation, specific configurations and details are set forth in order to provide a thorough understanding of the present invention. However, it will be apparent to one skilled in the art that the present invention may be practiced without the specific details presented herein. Furthermore, well known features may be omitted or simplified in order not to obscure the present invention.

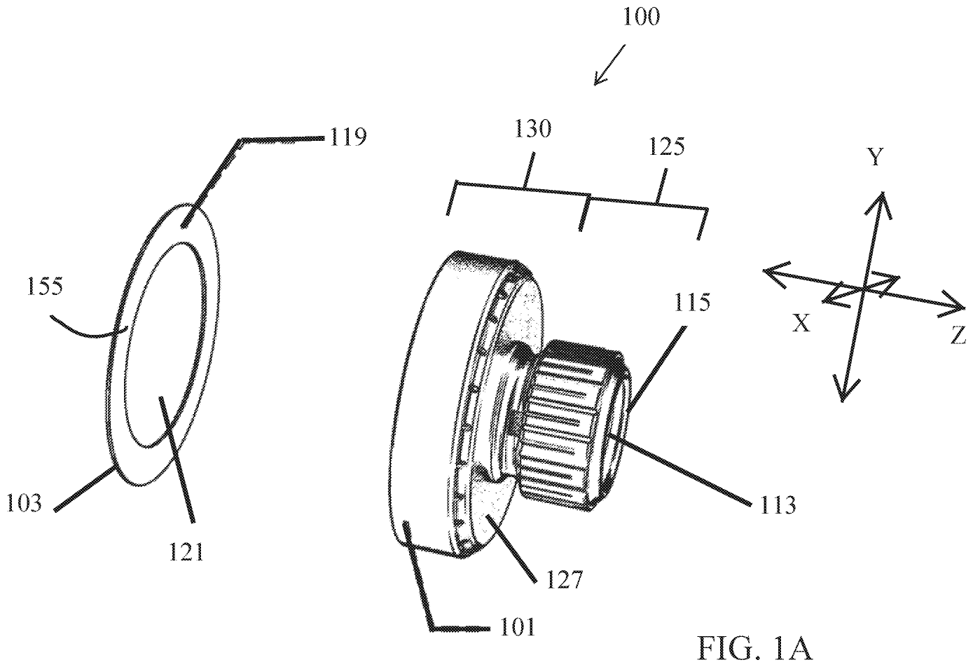

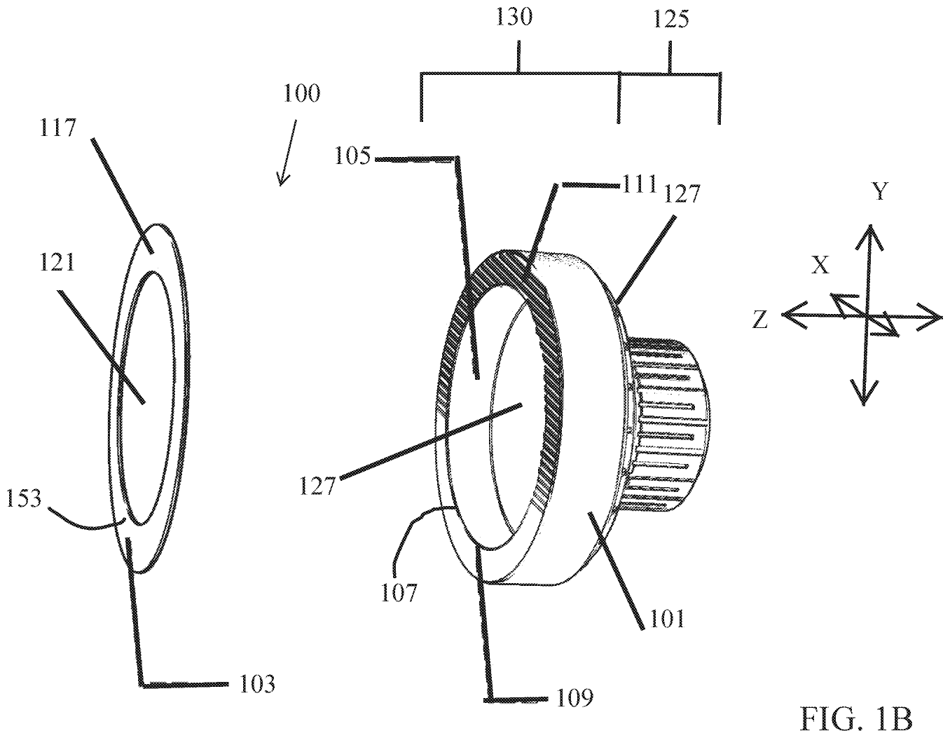

Reference is made to FIGS. 1A-B, which are perspective views of a mount connector 100 for an electronic device (not shown). In some embodiments, the mount connector 100 may include a mount body 101.

In some embodiments, a plate 103 may further be provided. In some embodiments, plate 103 of the mount connector 100 may include an attachment surface 117 on a first face 153 of the plate 103, a metal surface 119 on a second face 155 of the plate 103, and an aperture 121 extending through the first face 153 and the second face 155 of the plate 103. In some embodiments, attachment surface 117 may have an adhesive surface.

In some embodiments of the invention, plate 103 may have a circular shape. In these embodiments, the circular shape may reduce the amount of surface space that the plate occupies on a surface of the electronic device when the plate 103 is connected to the surface. In some embodiments of the invention, the surface of the electronic device may be a surface of a cover of the electronic device. In some embodiments, plate 103 may be shaped to conform to an outline of a protrusion affixed to or otherwise integral with the surface of an electronic device (or of a cover thereof), or to a portion of such outline.

In some embodiments, body 101 of the mount connector 100 may include a first cavity 105 having a first opening 107 in an exterior surface of a first part 130 of body 101. In some embodiments, body 101 may include a second part 125. In various embodiments, second part 125 may include any number of fastening, mounting, or connecting mechanisms for fastening, mounting, or otherwise connecting body 101 to another structure. For example, as described here, in some embodiments, second part 125 may be include a ball-socket enclosure for connecting body 101 to a ball mount.

In some embodiments, second part 125 may include, for example, a button, clasp, clip, snap, Velcro®, adhesive, zipper, loop, strap, hook, string, staple, cord, hinge, buckle, bolt, screw, nail, pin, suction cup, magnet, etc., any of which may be further adapted to fasten, mount, or connect body 101 to another structure, e.g., to an internal surface of a vehicle, to apparel, to a body part such as an arm or wrist, etc. Of course, those of ordinary skill in the relevant art will recognize that other combinations are may be further provided in other embodiments. In some embodiments, body 101 may further include a second cavity 113 having a second opening 115 in an exterior surface of second part 125 of body 101, e.g., for connecting body 101 to a ball mount. For example, in some embodiments, second part 125 may be a twist-style tightenable ball socket configured to receive, in cavity 113, a ball mount (such ball mount being fastenable to a surface, e.g., via an adhesive, suction cup, clip, etc.

In some embodiments, body 101 of mount connector 100 may further include a magnetic surface 111. In some embodiments, body 101 may include or integrate a magnet or magnetic surface in one or more locations of body 101, for example, at back surface 127, along an interior wall of first cavity 105, etc. In some embodiments, magnetic surface 111 of the mount connector 100 may be located on a portion of the external surface 109 of the body 101 surrounding the first opening 107. In some embodiments, magnetic surface 111 of the mount connector 100 and the metal surface 119 of the plate 103 may have corresponding sizes and shapes to enable the magnetic surface 111 of the mount connector 100 to magnetically connect to the metal surface 119 of the plate 103. In some embodiments of the invention, the magnetic surface 111 and metal surface 119 have the same size and shape.

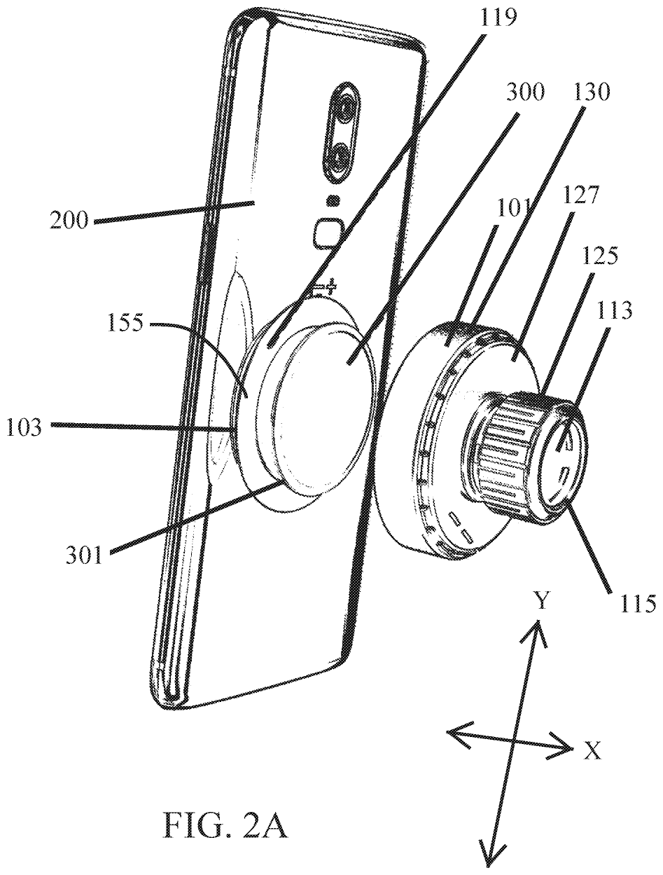

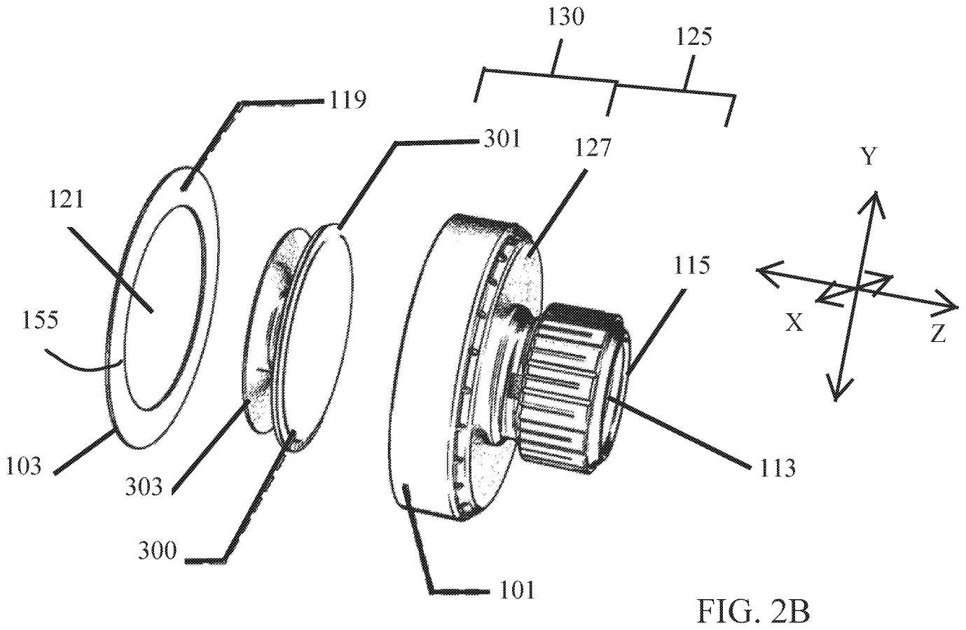

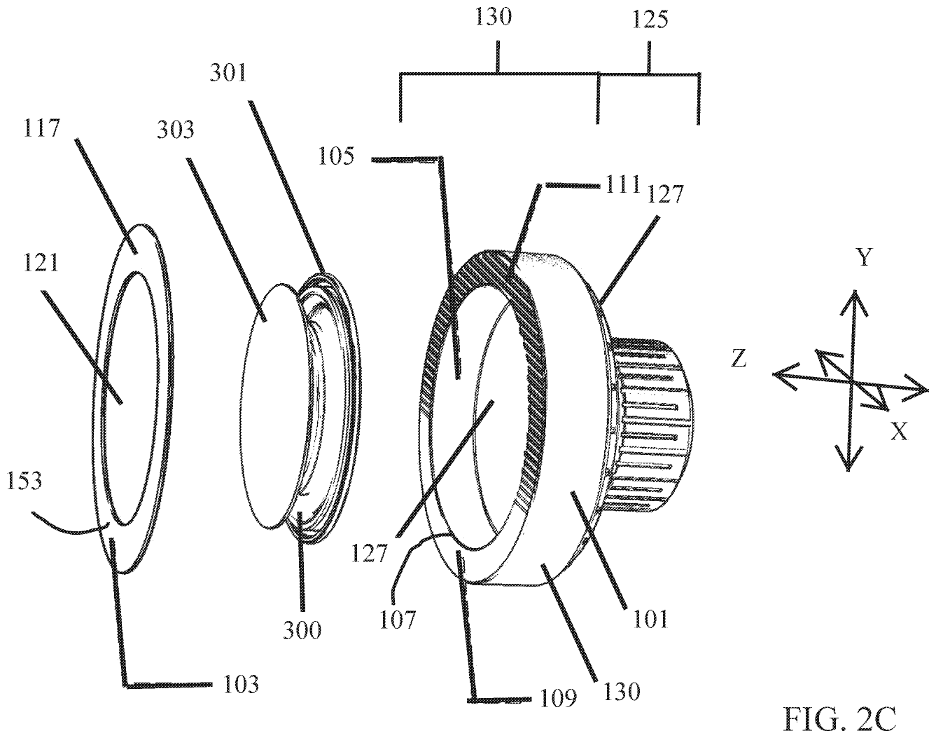

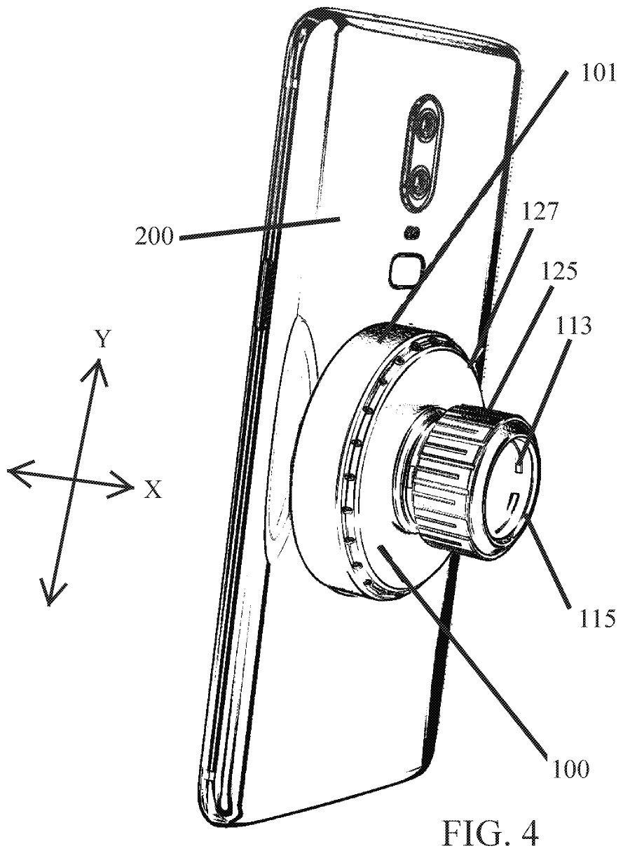

In some embodiments, second opening 115 of body 101 may be located on a different side of body 101 than the side that the first opening 107 and the magnetic surface 111 are located, such that second opening 115 is not obstructed by the electronic device when the body 101 is magnetically connected to plate 103 and plate 103 is connected to an electronic device, e.g., electronic device 200 (see, FIG. 2A and FIG. 4). For example, second opening 115 may be located on a side of body 101 that is at least 90° from the side of the body 101 than the first opening 107. In some embodiments of the invention, the first opening 107 and the second opening 115 are located on opposite sides of the body 101.

In some embodiments of the invention, the second part 125 of the body 101 may extend from a back surface 127 of body 101. The back surface 127 may be located on an opposite side of the body 101 than the first opening 107. The back surface 127 may separate the first cavity 105 and second cavity 113. In some embodiments of the invention, the first cavity 105 may be connected to the second cavity 113. Of course, in other embodiments of the invention, the second part 125 of the body 101 may extend from any other surface of body 101.

Reference is made to FIGS. 2A-C, which are perspective views of a mount connector 100 for an electronic device 200, according to some embodiments of the invention.

As can be seen in FIG. 2, the plate 103 of the mount connector 100 may be configured to be attached to a surface of the electronic device 200. For example, in some embodiments, the attachment surface 117 of the plate 103 may be attached to a surface of the electronic device 200, such as a cell phone, a tablet, or any other hand-held electronic device. In some embodiments of the invention, an adhesive, such as glue or cement, may be located on the second face 155 of the plate 103, such that the attachment surface 117 is an adhesive surface. The adhesive may be covered, such that the adhesive is not exposed to air or attached to unintended objects before the adhesive on the second face 155 is adhered to the electronic device 200.

As can be seen in FIGS. 2A-C, the aperture 121 in the plate 103 may be sized and shaped to allow a protrusion, e.g., protrusion 300, such as a clip, a ring stand grip, or any other grip extending from the surface of the electronic device 200, to pass through aperture 121 of plate 103 and allow the plate 103 to fit around or partially around the protrusion 300 while the attachment surface 117 is coupled to the surface of the electronic device 200. For example, aperture 121 may have a height and width that corresponds to a height and width of a largest cross-sectional area 301 of the protrusion 300.

In some embodiments of the invention, aperture 121 may have the same or approximately the same height and width as the largest cross-sectional area 301 of the protrusion 300. For example, if the largest cross-sectional area 301 of the protrusion 300 has a circular shape, then the aperture 121 of the plate 103 may have a circular shape with a same diameter as the largest cross-sectional area 301 of the protrusion 300. If the largest cross-sectional area 301 has an oval shape, then the aperture 121 has an oval shape with same sized major and minor axes as the largest cross-sectional area 301. Of course, other shapes are contemplated, e.g., square, rectangular, oval, etc., or part thereof, to accommodate a shape of protrusion 300, electronic device 200, and/or first part 130.

In some embodiments of the invention, the aperture 121 may have a greater height and width than the largest cross-sectional area 301 of the protrusion 300.

The protrusion 300 may have a base 303 which may be connected to the surface of the electronic device 200. The base 303 may have an adhesive surface connected to the surface of the electronic device 200.

In some embodiments, e.g., when the base 303 has the largest cross-sectional area of the protrusion 300 (e.g., the largest height and width), aperture 121 in the plate 103 may have a corresponding shape and area to allow the base 303 to sit within the aperture 121 when the base 303 and the attachment surface 117 are attached to the surface of the electronic device 200. For example, the height and width of the aperture 121 may be greater than or equal to the height and width of the cross-sectional area of base 303.

In some embodiments of the invention, the height, width, and shape of the aperture 121 may be the same as the height, width, and shape of the cross-section of base 303, such that the base 303 fits within the aperture 121 and the inner walls of the aperture 121 resist movement of the base 303 in two perpendicular directions. For example, if a plane parallel to the attachment surface 117 and metal surface 119 is defined to extend in the x and y direction, then the inner walls of the aperture 121 resist movement of the base 303 in the x and y directions when the base 303 and the attachment surface 117 are attached to the surface of the electronic device 200.

In some embodiments, e.g., if the largest cross-sectional area 301 of the protrusion 300 is not the base 303, and the aperture 121 has a height and width that is greater than or equal to the height and width of the cross-sectional area of the base 303 but less than the height and width of the largest cross-sectional area 301 of the protrusion 300, then the plate 103 may be adhered to the surface of the electronic device 200 before the base 303 is adhered. In some embodiments, aperture 121 may be configured, e.g., with slats, indents, or other openings to accommodate the wider cross-section.

The first cavity 105 and the first opening 107 of the body 101 may be sized and shaped to accept the protrusion 300. The first opening 107 and a first section of the first cavity 105 may have a height and width that is at least as large as the height and width of the largest cross-sectional area 301 of the protrusion 300. In some embodiments of the invention, the first opening 107 and the first section of the first cavity 105 each have a same or approximately same or similar height and width as the largest cross-sectional area 301 of the protrusion 300, such that when the protrusion 300 is inside the first cavity 105, the inner walls of the first cavity 105 prevent or substantially hinder movement of the protrusion 300 in at least one direction in which a plane parallel to first opening 107 extends. For example, if the plane parallel to the first opening 107 is defined to extend in the x and y direction, then the walls (or a portion thereof) of the first cavity 105 may prevent movement of the protrusion 300 in at least one direction within the x-y plane (e.g., upward, downward, sideways, and/or angularly) when the protrusion 300 is inserted (e.g., partially or entirely) into first cavity 105.

In some embodiments, e.g., where the height and/or width of the first section of the first cavity 105 is greater than the height and/or width of the cross-sectional area 301 of the protrusion, the first cavity 105 may comprise a second section having a height, width, and shape that is equal to the height, width, and shape of the largest cross-sectional area 301 of the protrusion 300. In such embodiments, e.g., when the protrusion 300 is inside the first cavity 105, the walls of the second section of the first cavity 105 may prevent, restrain, or otherwise limit movement of the protrusion 300 in at least one direction within the x-y plane, as defined above. In some embodiments, the first section of the first cavity 105 may be closer to the first opening 107 than the second section of the first cavity 105.

In embodiments, where the protrusion 300 has a section with a cross-sectional area smaller than the largest cross-sectional area 301 of the protrusion 300, and that smaller cross-sectional section extends further away from the electronic device 200 than the largest cross-sectional area 301 of the protrusion 300, then the first cavity 105 may comprise a third section having a height, width, and shape that corresponds to the height, width, and shape of the cross-sectional area of the section of the protrusion 300 that extends further away from the electronic device 200 than the section with the largest cross-sectional area 301.

For example, when the base 303 is the largest cross-sectional area of the protrusion 300, then each section of the first cavity 105 may have a height and width greater than or equal to the height and width of the second largest cross-sectional area of the protrusion 300, and at least a section of the first cavity 105 that aligns with the second largest cross-sectional area of the protrusion 300 has a same height, width, and shape as the second largest cross-sectional area, to prevent the protrusion 300 from moving in at least one direction within the x-y plane, as defined above.

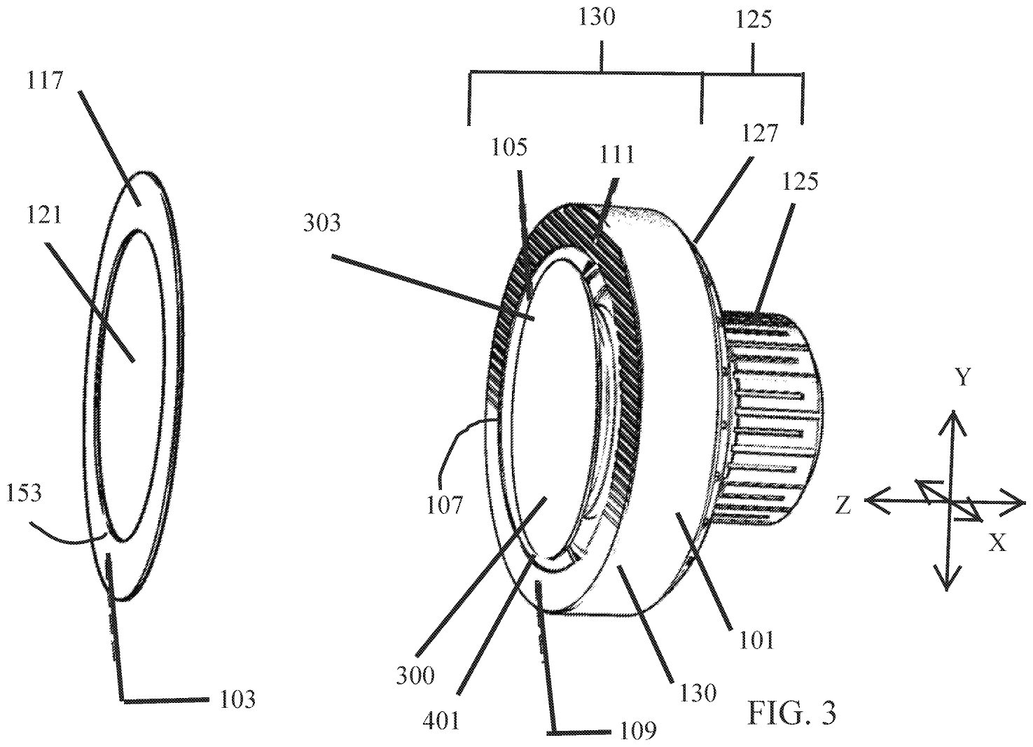

In some embodiments of the invention, the metal surface 119 may have a greater surface area than the magnetic surface 111. For example, as can be seen in FIG. 3, a perspective view of the mount connector 100 holding a protrusion 300 extending from a back of the electronic device (not shown), when the base 303 is not the largest cross-sectional area of the protrusion 300, there may be a gap 401 between the base 303 and a rim of the first opening 107, and not connected to a plate, according to some embodiments of the invention. If the base 303 is not the largest cross-sectional area of the protrusion 300 and the height, width, and shape of the aperture 121 in the plate 103 is the same as the height, width, and shape of the cross-sectional area of the base 303, then, in some embodiments, the surface area of the metal surface 119 of the plate 103 may be equal to the cross-sectional area of the gap 401 plus the surface area of the base 303 of the protrusion 300.

In some embodiments of the invention, the depth of the first cavity 105 may be long enough to allow all or substantially all of protrusion 300, e.g., including or excepting for the base 303 to fit within and/or be received by the first cavity 105, e.g., when the metal surface 119 and the magnetic surface 111 are magnetically connected. For reference, the depth of the first cavity 105 is in a z direction which is perpendicular to both the x and y directions defined above. In some embodiments, the depth and/or angle of first cavity 105 may be sufficient such that no magnet or adhesive is required to restrain electronic device 200 against mount connector 100 via protrusion 300.

In some embodiments, each cross-section of the second part 125 of the body 101 may have a smaller height and width than each cross-section of the first part 130 of the body 101. The height and width of each cross-section of the second part 125 may be smaller than the height and width of each section of the first cavity 105. The height and width of each part of the first cavity 105 may be greater than the height and width of each part of the second cavity 113. The first opening 107 may have a greater height and width than the height and width of the second opening 115.

The second cavity 113 and second opening 115 may be sized and shaped to accept a male connector (not shown) of a mount (not shown), e.g., a ball mount. The mount may be a car mount, a wall mount, or any other mount for an electronic device. The second cavity 113 may include a female connector (not shown), located in-side the second cavity 113, configured to removably connect the mount connector 100 to a male connector (not shown) of a mount (not shown) or a selfie-stick (not shown). For example, an inside of the walls of the second cavity 113 may have threading (not shown), and may be tightenable around a ball mount received therein via, e.g., a twisting mechanism for reducing an internal width of second cavity 113 and/or of second opening 115.

Reference is made to FIG. 4 which is a perspective view of the mount connector 100 in an attached position, according to some embodiments of the invention.

One skilled in the art will appreciate that the present invention can be practiced by other than the described embodiments, which are presented for purposes of illustration and not limitation. In addition, different embodiments are disclosed herein, and features of certain embodiments may be combined with features of other embodiments, such that certain embodiments maybe combinations of features of multiple embodiments. Further, since numerous modifications and changes will readily occur to those skilled in the art, it is not desired to limit the invention to the exact construction and operation shown and described, and accordingly, all suitable modifications and equivalents may be resorted to, without departing from the scope or spirit of the invention as defined in the appended claims.

What is claimed is:

1. A mount connector for a portable electronic device having a protrusion extending from a surface of the portable electronic device or a surface of a cover of the portable electronic device, the mount connector comprising:
a body comprising a first part, the first part of the body comprising:
a first cavity having a first opening on an external surface of the first part of the body, wherein the first cavity and first opening are sized and shaped to accept and limit movement of the protrusion in at least one direction while the mount connector is connected to the electronic device, and
a magnetic surface located on a portion of the external surface of the first part of the body surrounding the first opening, wherein the magnetic surface is configured to connect the mount connector to the portable electronic device, the cover of the portable electronic device, or a metal surface integrated therewith.

2. The mount connector of claim 1, wherein:
a height of the first opening and a height of each part of a first section of the first cavity is greater than or equal to a height of a greatest cross-sectional area of the protrusion;
a width of the first opening and a width of each part of the first section of the first cavity is greater than or equal to a width of the greatest cross-sectional area of the protrusion; and
a height and a width of a second section of the first cavity is equal to the height and width of the greatest cross-sectional area of the protrusion, such that the second section of the first cavity limits the protrusion from moving in at least one direction within an X-Y plane parallel to at least one of the first opening and the first cavity when the first cavity holds the protrusion; and wherein:
the width of the first opening and the first section of the first cavity runs in an X direction;
the height of the first opening and first section of the first cavity runs in a Y direction, wherein the Y direction is perpendicular to the X direction.

3. The mount connector of claim 1, wherein a height and width of the first opening and each part of a first section of the first cavity is equal to a height and width of the greatest cross-sectional area of the protrusion, such that the first cavity prevents the protrusion from moving in at least one direction of a plane of an X direction and a Y direction when the first cavity holds the protrusion; wherein:
the width of the first opening and first section of the first cavity runs in the X direction;
the height of the first opening and first section of the first cavity runs in the Y direction, wherein the Y direction is perpendicular to the X direction.

4. The mount connector of claim 1, further comprising a plate, the plate comprising:
an adhesive surface configured to be attached to the surface of the portable electronic device or the back of the cover of the portable electronic device;
a metal surface, located on an opposite face of the plate, wherein the magnetic surface and the metal surface are sized and shaped to magnetically connect the plate and the body; and
a plate aperture extending from the adhesive surface to the metal surface, the plate aperture sized and shaped to pass over the protrusion when the magnetic surface and the metal surface are magnetically connected.

5. The mount connector of claim 4, wherein:
the plate aperture, the first opening, and each part of the first cavity each have a height that is greater than or equal to a height of a greatest cross-sectional area of the protrusion; and
the plate aperture, the first opening, and each part of the first cavity each have a width that is greater than or equal to a width of the greatest cross-sectional area of the protrusion.

6. The mount connector of claim 5, wherein the cross-sectional area of at least one of the plate aperture, the opening, and at least a part of the first cavity is equal to a greatest cross-sectional area of the protrusion.

7. The mount connector of claim 5, wherein a surface area of the magnetic surface has a same size and shape as a surface area of the metal surface.

8. The mount connector of claim 1, further comprising a second part of the body, the second part of the body comprising a second cavity having a second opening on an external surface of the second part of the body.

9. The mount connector of claim 8, wherein the second cavity comprises a female connector configured to connect with a male connector of a mounting device.

10. The mount connector of claim 9, wherein the mounting device is a car mount.

11. The mount connector of claim 8, wherein the second opening of the second part of the body is located on a side of the body that is at least 90° from a side of the body than the first opening of the first part of the body is located, such that the second cavity is accessible through the second opening while the mount connector is connected to the electronic device.

12. The mount connector of claim 8, wherein:
a height of the first opening is greater than a height of the second opening; and
a width of the first opening is greater than a width of the second opening.

13. The mount connector of claim 8, wherein each part of the first part of the body has a greater cross-sectional area than each part of the second part of the body.

14. The mount connector of claim 13, wherein the second part of the body extends from a back surface of the first part of the body, and the back surface of the first part of the body is located on an opposite side of the first part of the body than the first opening.

15. A mount connector for a portable electronic device having a protrusion extending from a back of the portable electronic device or a back of a cover of the portable electronic device, the mount connector comprising:
a body comprising:
a first cavity having a first opening on an external surface of the body, and
a magnetic surface located on a portion of the external surface of the body surrounding the first opening; and
a plate comprising:
an adhesive surface configured to be attached to the back of the portable electronic device or the back of the cover of the portable electronic device;
a metal surface, located on an opposite face of the plate, wherein the magnetic surface and the metal surface are sized and shaped to magnetically connect the plate and the body; and
a plate aperture extending from the adhesive surface to the metal surface.

16. The mount connector of claim 15, wherein a surface area of the magnetic surface and the metal surface are sized and shaped for magnetically connecting the magnetic surface and the metal surface.

17. The mount connector of claim 15, wherein:
the plate aperture, the first opening, and each part of a first section of the first cavity each have a height greater than or equal to a pre-determined height;
the plate aperture, the first opening, and each part of the first section of the first cavity each have a width greater than or equal to a pre-determined width; and
at least a part of the first cavity has a height and width that are equal to the pre-determined height and the pre-determined width, respectively.

18. The mount connector of claim 15, further comprising a second cavity having a second opening on the external surface of the body.

19. A mount connector for a portable electronic device having a protrusion extending from a back of the portable electronic device or a back of a cover of the portable electronic device, the mount connector comprising:
a body comprising a first part, the first part of the body comprising:
a first cavity having a first opening on an external surface of the first part of the body, wherein the first cavity and first opening are sized and shaped to accept and limit movement of the protrusion in at least one direction while the mount connector is connected to the electronic device, and
a second part of the body, the second part of the body comprising a second cavity having a second opening on an external surface of the second part of the body.

20. The mount connector of claim 19, wherein first cavity is configured to limit movement of the protrusion in at least one direction within a plane parallel to at least one of the first opening and the first cavity.
